(19) United States
(12) Patent Application Publication
(10) Pub. No.: US 2013/0043521 A1
(43) Pub. Date: Feb. 21, 2013

(54) 3-DIMENSIONAL NON-VOLATILE MEMORY DEVICE AND METHOD OF MANUFACTURING THE SAME

(71) Applicant: Young Kyun JUNG, Gyeonggi-do (KR)

(72) Inventor: Young Kyun JUNG, Gyeonggi-do (KR)

(21) Appl. No.: 13/585,336

(22) Filed: Aug. 14, 2012

(30) Foreign Application Priority Data
Aug. 16, 2011 (KR) 10-2011-0081288

(51) Int. Cl. H01L 29/788; H01L 21/762

(52) U.S. Cl. 257/315; 438/424; 257/E29.3; 257/E21.546

(57) ABSTRACT

A method of manufacturing a 3-Dimensional (3-D) non-volatile memory device includes forming first material layers and second material layers alternately, forming at least one first trench by etching the first material layers and the second material layers, forming floating gate regions by recessing the second material layers, exposed to the first trench, forming a first charge blocking layer on surfaces of the first trench and the floating gate regions, forming a first conductive layer on the first charge blocking layer, etching the first conductive layer on the upper side of the first trench, forming a second charge blocking layer on the first charge blocking layer exposed by etching the first conductive layer, and forming floating gates in the respective floating gate regions by etching the first conductive layer.

### CROSS-REFERENCE TO RELATED APPLICATION

Priority to Korean patent application number 10-2011-0081288 filed on Aug. 16, 2011, the entire disclosure of which is incorporated by reference herein, is claimed.

### BACKGROUND

Embodiments of this disclosure relate to a semiconductor device and a method of manufacturing the same and, more particularly, to a 3-Dimensional (3-D) non-volatile memory device and a method of manufacturing the same.

A non-volatile memory device retains data stored therein although the supply of power is cut off. As the integration degree of 2-D memory devices in each of which memory cells are fabricated over a silicon substrate as a single layer is reaching limits, a 3-D non-volatile memory device in which memory cells are stacked on a silicon substrate in a vertical direction thereto is being proposed.

The structure and features of a known 3-D non-volatile memory device are described in detail below.

FIG. 1 is a sectional view illustrating the structure of a known 3-D charge trap type non-volatile memory device.

As shown in FIG. 1, the known 3-D charge trap type non-volatile memory device includes channels CH protruding from a substrate 10 and a plurality of memory cells stacked along each of the channels CH.

More particularly, the known 3-D charge trap type non-volatile memory device sequentially includes a lower select gate LSG, a plurality of memory cells MC, and an upper select gate USG over the substrate 10 in which a source region (not shown) is formed. Bit lines BL coupled to the channels CH are provided over the upper select gate USG.

The plurality of memory cells MC coupled in series between the lower select gate LSG and the upper select gate USG form one string STRING. A plurality of strings STRING are arranged to extend in a vertical direction to the substrate 10.

In FIG. 1, reference numerals 11, 14, and 17 denote interlayer insulating layers, reference numeral 12 denote a lower select line, reference numeral 15 denotes word lines, and reference numeral 18 denotes an upper select line. Furthermore, reference numerals 13 and 19 denote gate insulating layers, and reference numeral 16 denotes a charge blocking layer, a charge trap layer, and a tunnel insulating layer.

In this structure, data is stored by charging or discharging electric charges into or from the charge trap layer. The known 3-D charge trap layer non-volatile memory device, however, may have lower performance than a floating gate type non-volatile memory device for storing data by charging or discharging electric charges into or from the floating gate.

In particular, the known 3-D charge trap layer non-volatile memory device has a slow program/erase operation speed and a poor data retention characteristic as compared with the floating gate type non-volatile memory device. Furthermore, a data retention characteristic is further deteriorated because the charge trap layers of the plurality of memory cells stacked along the channel are coupled in the structure of the 3-D non-volatile memory device.

### BRIEF SUMMARY

An exemplary embodiment of the present invention relates to a 3-D floating gate type non-volatile memory device for storing data by charging or discharging electric charges into or from a floating gate and a method of manufacturing the same.

In accordance with an embodiment of the present invention, a method of manufacturing a 3-D non-volatile memory device includes forming first material layers and second material layers alternately, forming at least one first trench by etching the first material layers and the second material layers, forming floating gate regions by recessing the second material layers, exposed to the first trench, forming a first charge blocking layer on surfaces of the first trench and the floating gate regions, forming a first conductive layer on the first charge blocking layer, etching the first conductive layer on an upper side of the first trench, forming a second charge blocking layer on the first charge blocking layer exposed by etching the first conductive layer, and forming floating gates in the respective floating gate regions by etching the first conductive layer.

In accordance with another embodiment of the present invention, a 3-D non-volatile memory device includes word lines and interlayer insulating layers alternately stacked over a substrate, at least one first channel protruding from the substrate and penetrating the word lines and the interlayer insulating layers, floating gates interposed between the first channel and the interlayer insulating layers and surrounding the first channel, a first charge blocking layer interposed between the word lines and the floating gates, and a second charge blocking layer formed on the first charge blocking layer surrounding a top word line of the word lines.

In accordance with an embodiment of the present invention, a method of manufacturing a 3-D non-volatile memory device includes forming first material layers and second material layers alternately; forming at least one trench by etching the first material layers and the second material layers; recessing the second material layers exposed to the first trench; forming a first charge blocking layer on surfaces of the first material layers and the recessed second material layers; forming a first conductive layer on the first charge blocking layer; performing a first etching process to remove the first conductive layer formed on an upper region of the trench; forming a second charge blocking layer on the first charge blocking layer exposed by the first etching process; and performing a second etching process to form floating gates by removing the first conductive layer formed on a center region of the trench.

### BRIEF DESCRIPTION OF THE DRAWINGS

FIG. 1 is a sectional view illustrating the structure of a known 3-D charge trap type non-volatile memory device;

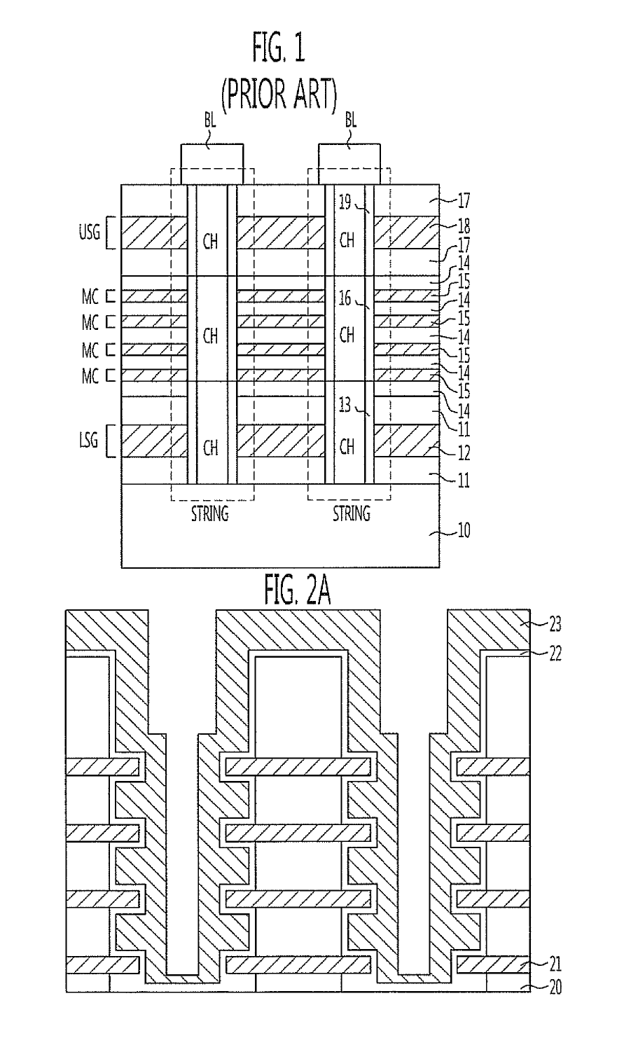

FIGS. 2A to 2F are sectional views illustrating a method of manufacturing a 3-D non-volatile memory device according to a first embodiment of the present invention;

FIGS. 3A and 3B are sectional views illustrating a method of manufacturing a 3-D non-volatile memory device according to a second embodiment of the present invention;

FIGS. 4A and 4B are sectional views illustrating a method of manufacturing a 3-D non-volatile memory device according to a third embodiment of the present invention;

FIG. 5 is a sectional view showing a structure of a 3-D non-volatile memory device according to a fourth embodiment of the present invention;

FIG. 6 is a sectional view showing a structure of a 3-D non-volatile memory device according to a fifth embodiment of the present invention;

FIG. 7 shows a construction of a memory system according to an exemplary embodiment of the present invention; and

FIG. 8 shows a construction of a computing system according to an exemplary embodiment of the present invention.

### DESCRIPTION OF EMBODIMENTS

Hereinafter, some exemplary embodiments of the present disclosure will be described in detail with reference to the accompanying drawings. The figures are provided to enable those of ordinary skill in the art to make and use the present invention according to the exemplary embodiments of the present invention.

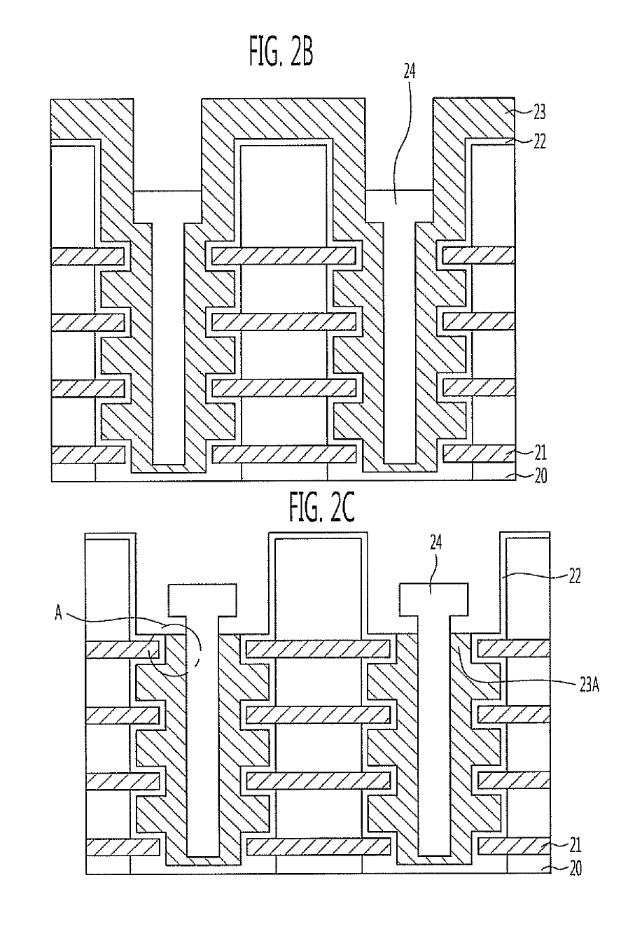

FIGS. 2A to 2F are sectional views illustrating a method of manufacturing a 3-D non-volatile memory device according to a first embodiment of the present invention.

As shown in FIG. 2A, a plurality of first material layers 21 and a plurality of second material layers 20 are alternately formed over a substrate (not shown) in which given substructures are formed.

The first material layers 21 and the second material layers 20 are used to form a plurality of word lines stacked over the substrate. The first material layers 21 are used to form the word lines in a subsequent process, and the second material layers 20 are used to form interlayer insulating layers each for separating the stacked word lines from each other. Accordingly, the number of first material layers 21 and second material layers 20 is determined by the number of memory cells to be stacked.

The thickness of each of the first material layer and the second material layer 20 is determined by taking the role of each layer into consideration. For example, after forming floating gate regions by recessing the second material layers 20 to have a specific thickness in a subsequent process, a second charge blocking layer and a floating gate may be formed within the floating gate region. Accordingly, the second material layer 20 may have a thicker thickness than the first material layer 21 by taking the thickness of the second charge blocking layer and the floating gate into consideration. For another example, the second material layer 20 formed at the top, from among the second material layers 20, functions as an etch stop layer in a subsequent polishing process. Accordingly, the second material layer 20 formed at the top may have a thicker thickness than the second material layers 20 on the lower side. For example, the thickness of each of the first material layer 21 and the second material layer 20 may be 50 to 500 Å.

Materials for forming the first material layers 21 and the second material layers 20 may be determined by taking the role of each layer and a manufacturing process into consideration. The first material layers 21 and the second material layers 20 may be made of materials having a high etch selectivity ratio to each other. Furthermore, the first material layers 21 may be formed of a conductive layer or sacrificial layer for the word lines, and the second material layers 20 may be formed of an interlayer insulating layer or a sacrificial layer.

For example, the first material layers 21 may be formed of a conductive layer for the word lines, such as a polysilicon layer, and the second material layers 20 may be formed of an interlayer insulating layer, such as an oxide layer.

For another example, the first material layers 21 may be formed of a doped polysilicon layer for the word line, and the second material layers 20 may be formed of an undoped polysilicon layer or an amorphous silicon layer, that is, a sacrificial layer. The doped polysilicon layer may be a polysilicon layer into which dopants, such as boron (Br), have been injected. In this case, after forming a slit, the second material layers 20 are recessed. Interlayer insulating layers, such as an oxide layer, are filled in the recessed regions, thereby separating the stacked word lines from each other.

For yet another example, the first material layers 21 may be formed of a sacrificial layer, such as a nitride layer, and the second material layers 20 may be formed of an interlayer insulating layer, such as an oxide layer. In this case, after forming a slit, the first material layers 21 are recessed. Conductive layers, such as a polysilicon layer or a tungsten layer, are filled in the recessed regions, thereby forming the word line.

In the first embodiment, an example that the first material layers 21 are formed of a conductive layer and the second material layers 20 are formed of an interlayer insulating layer is described.

Next, after forming first trenches by etching the first material layers 21 and the second material layers 20, the second material layers 20 exposed to the inner walls of the first trench is recessed by a specific depth. As the second material layers 20 are recessed, the first material layers 21 protrude into the inside of the first trench, and thus the inner walls of the first trench have a rugged profile.

In regions from which the second material layers 20 are recessed, as described above, respective floating gates will be formed in a subsequent process and those regions are hereinafter referred to as floating gate regions.

A first charge blocking layer 22 is formed on the inner walls of the first trench in which the floating gate regions are formed. The first charge blocking layer 22 functions to prevent electric charges, stored in the floating gates, from moving to the word lines. The first charge blocking layer 22 may have a stack structure, including an oxide layer, a nitride layer, and an oxide layer, or it may be made of high-k material.

A first conductive layer 23 is formed on the first charge blocking layer 22. The first conductive layer 23 is formed on the inner surfaces of the first trench on which the first charge blocking layer 22 is formed. The first conductive layer 23 is formed not to fill the central region of the first trench.

As shown in FIG. 2B, a sacrificial layer 24 is formed within the first trench so that the central region of the first trench is filled. For example, the sacrificial layer 24 may be formed within the first trench by forming the sacrificial layer 24 over the entire structure in which the first trench is formed and then etching back the sacrificial layer 24.

The sacrificial layer 24 defines what extent the first conductive layer 23 is etched to through a primary etch process. It is preferred that the sacrificial layer 24 be formed such that a top surface of the sacrificial layer 24 is equal to or higher than a top surface of the first material layer 21 formed at the top.

It is also preferred that the sacrificial layer 24 be made of material having a high etch selectivity ratio to the first conductive layer 23. Furthermore, it is preferred that the sacrificial layer 24 have an excellent gap-fill characteristic because the sacrificial layer 24 is to be filled in the central region having a high aspect ratio. For example, the sacrificial layer 24 may be formed of a Spin On Dielectric (SOD) layer or a flowable oxide layer, such as an oxide layer based on polysilazane (PSZ). It is preferred that the sacrificial layer 24 have a thickness of 100 to 2000 Å.

As shown in FIG. 2C, a primary etch process is performed on the first conductive layer 23 formed on the upper side of the first trenches. The upper side may range from the opening part of the first trench to a top surface of the first material layers 21 formed at the top.

In the exemplary embodiment, the first conductive layer 23 is etched at least twice in order to prevent the first charge blocking layer 22, formed on the upper side of the first trenches, from being damaged in a process of etching the first conductive layer 23. Since the floating gate regions have been formed by recessing the second material layers 20, the first material layers 21 protrude into the inside of the first trench. Accordingly, when etching the first conductive layer 23 in order to form floating gates, the first charge blocking layer 22 surrounding the first material layer 21 formed at the top may be etched because etching is concentrated on the first charge blocking layer 22, and the first material layers 21 on the lower side may also be exposed and damaged.

In the exemplary embodiment, however, the primary etch process is performed on the first conductive layer 23 in the state that the sacrificial layer 24 has been filled in the central region of the first trench. Thus, the first conductive layer 23 formed in the lower region and bottom of the first trench remains intact, and the first conductive layer 23 formed on the upper side of the first trenches may be selectively etched. That is, damage to the first charge blocking layer 22 may be minimized because the primary etch process is performed so that only the first conductive layer 23 formed on the upper side of the first trenches is etched.

The etching of the first conductive layer 23 may be performed using an etch-back etch process or a wet etch process. In FIG. 2C, the etched first conductive layer is indicated by reference numeral 23A.

As shown in FIG. 2D, a second charge blocking layer 25 is formed on the first charge blocking layer 22 exposed by the etching of the first conductive layer 23. Here, the second charge blocking layer 25 is formed to range from the opening part of the first trench to the top surface of the first material layers 21 formed at the top.

The second charge blocking layer 25 functions to supplement a charge blocking layer etched in the process of etching the first conductive layer 23. The second charge blocking layer 25 is formed on the upper side of the first trenches wherein the first charge blocking layer 22 is likely to be damaged. That is, the second charge blocking layer is formed between the primary etch process and a secondary etch process so that the first charge blocking layer 22 damaged in the primary etch process is supplemented, and the first and second charge blocking layers 22 and 25 may sufficiently function as a charge blocking layer although the second charge blocking layer 25 is partially etched in the secondary etch process.

The second charge blocking layer 25 is formed by considering the amount of a charge blocking layer that is etched in the process of etching the first conductive layer 23. The first charge blocking layer 22 and the second charge blocking layer 25 that finally remain have a total thickness enough to function as a charge blocking layer. For example, the sum of thicknesses of the first charge blocking layer 22 and the second charge blocking layer 25 may be 20 to 500 Å.

It is also preferred that top surfaces of the first sacrificial layers 24 be exposed so that the first sacrificial layers 24 are easily removed subsequently. To this end, after forming the second charge blocking layer 25 on the entire surface, a blanket etch process may be performed until the top surfaces of the first sacrificial layers 24 are exposed. In this case, it is preferred that the second charge blocking layer 25 be formed by considering the thickness of the second charge blocking layer 25 that is etched by the blanket etch process.

As shown in FIG. 2E, the first sacrificial layers 24 are removed. The first sacrificial layer 24 may be removed by a strip process.

Next, a plurality of floating gates 23B filled in the respective floating gate regions are formed by etching the second charge blocking layer 25, the first charge blocking layer 22, and the first conductive layer 23A. Here, the stacked floating gates 23B are separated from each other by removing the first conductive layer 23A formed on the inner walls and at the bottom of the first trench other than the floating gate regions.

In FIG. 2E, the second charge blocking layer etched in the process of forming the floating gates 23B is indicated by reference numeral 25A, and the etched first charge blocking layer is indicated by reference numeral 22A.

As shown in FIG. 2F, a tunnel insulating layer 26 is formed on the inner walls of the first trench in which the plurality of floating gates is formed. The tunnel insulating layer 26 functions as an energy barrier layer for Fowler-Nordheim (F-N) tunneling, and it may be formed of an oxide layer.

After a channel layer 27 is formed over the entire structure in which the tunnel insulating layer 26 is formed, a polishing process is performed. In FIG. 2F, the first charge blocking layer polished by the polishing process is indicated by reference numeral 22B, and the polished second charge blocking layer is indicated by reference numeral 25B.

Thus, the channel layer 27 is formed on the tunnel insulating layer 26. An example that the channel layer 27 is formed to fully fill the first trench is illustrated in FIG. 2F, but the channel layer 27 may be formed so that the central region of the first trench is not filled. In this case, an insulating layer is filled in the central region.

As a result, a plurality of memory cells are stacked along each of the channels protruding from the substrate. Here, at least one memory cell formed at the top, from among the plurality of memory cells, includes the first charge blocking layer 22B and the second charge blocking layer 25B. Accordingly, the at least one memory cell has a charge blocking layer which includes the first charge blocking layer 22B and the second charge blocking layer 25B and has a thicker thickness than charge blocking layers of the lower memory cells which include the first charge blocking layer 22B only.

In accordance with the exemplary embodiment, the 3-D non-volatile memory device in which one memory cell includes one floating gate and two control gate electrodes is fabricated. If the one memory cell is driven by the two control gate electrodes, the memory cells may be more easily driven by using a low program voltage and a low erase voltage. Furthermore, an interference effect may be further reduced as compared with a known art because the first charge blocking layer is formed to surround the entire surface of the floating gates.

Furthermore, in order to prevent the first charge blocking layer 22 formed on the upper side of the first trenches from being damaged in the process of etching the first conductive layer 23 to form the floating gates, the first conductive layer 23 is etched by twice etching processes, and the second charge blocking layer 25 is formed between the twice etching processes. In this case, the charge blocking layer and the highest word line may be protected in the process of etching the first conductive layer 23 in order to separate the floating gates from each other.

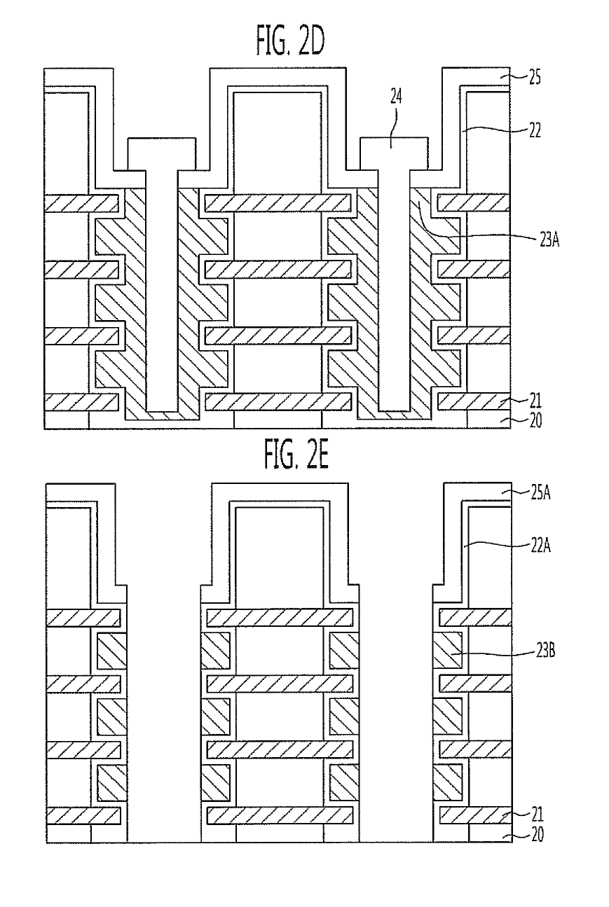

FIGS. 3A and 3B are sectional views illustrating a method of manufacturing a 3-D non-volatile memory device according to a second embodiment of the present invention.

The second embodiment relates to an example that a plurality of first material layers 21 is formed of a sacrificial layer, such as a nitride layer, and a plurality of second material layers 20 is formed of an interlayer insulating layer, such as an oxide layer. In the second embodiment, processes of forming floating gates 23B, a tunnel insulating layer 26, and a channel layer 27 after alternately forming the first material layers 21 and the second material layers 20 may be performed by using the processes described in the first embodiment, and thus only subsequent processes are described, for description purposes.

As shown in FIG. 3A, a slit is formed by etching the plurality of first material layers 21 and the plurality of second material layers 20 between the first trenches. In FIG. 3A, the second material layers etched in the process of forming the slits are indicated by reference numeral 20A.

The plurality of first material layers 21 exposed to the slits are recessed. In regions which the first material layers 21 are recessed from, as described above, word lines will be formed in a subsequent process and those regions are referred to as word line regions.

As shown in FIG. 3B, a second conductive layer is formed on the inner surfaces of the slits in each of which the word line regions are formed. A plurality of word lines 28 filled in the respective word line regions are formed by removing the second conductive layer formed on the inner walls and bottom of the slit other than the word line regions.

Next, an insulating layer 29 is filled in the slit.

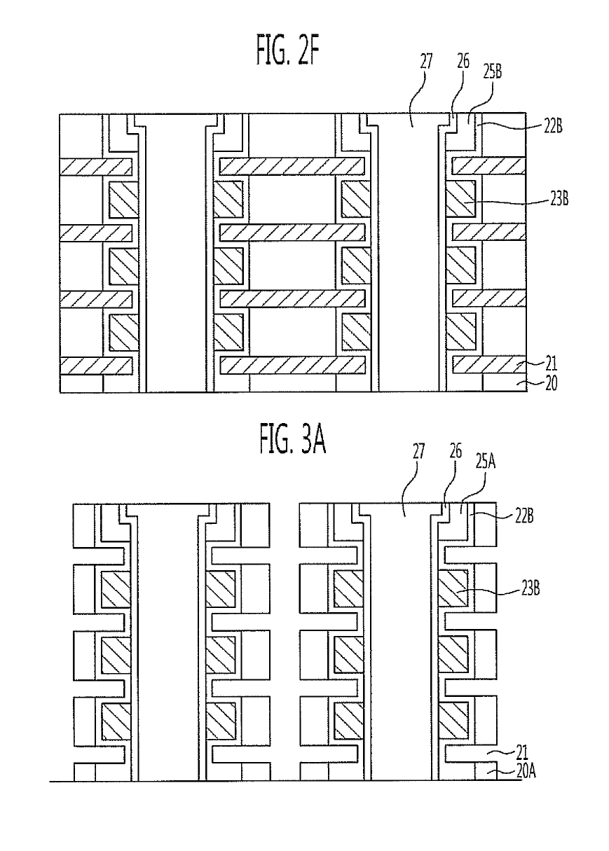

FIGS. 4A and 4B are sectional views illustrating a method of manufacturing a 3-D non-volatile memory device according to a third embodiment of the present invention.

The third embodiment relates to an example that a plurality of first material layers 21 is formed of a doped polysilicon layer for word lines, and a plurality of second material layers 20 is formed of an undoped polysilicon layer, that is, a sacrificial layer. In the third embodiment, processes of forming floating gates 23B, a tunnel insulating layer 26, and a channel layer 27 after alternately forming the first material layers 21 and the second material layers 20 may be performed by using the processes described in the first embodiment, and thus only subsequent processes are described, for description purposes.

As shown in FIG. 4A, a slit is formed by etching the plurality of first material layers 21 and the plurality of second material layers 20 between the first trenches. In FIG. 4A, the first material layers etched in the process of forming the slits are indicated by reference numeral 21A.

The plurality of second material layers 20 exposed to the slits are recessed. In regions which the second material layers 20 are recessed from, as described above, interlayer insulating layers will be formed in a subsequent process and those regions are referred to as insulating regions.

As shown in FIG. 4B, an insulating layer 30 is formed to fill the slits in each of which the plurality of insulating regions is formed. Accordingly, stacked word lines are electrically isolated from each other by the insulating layer 30.

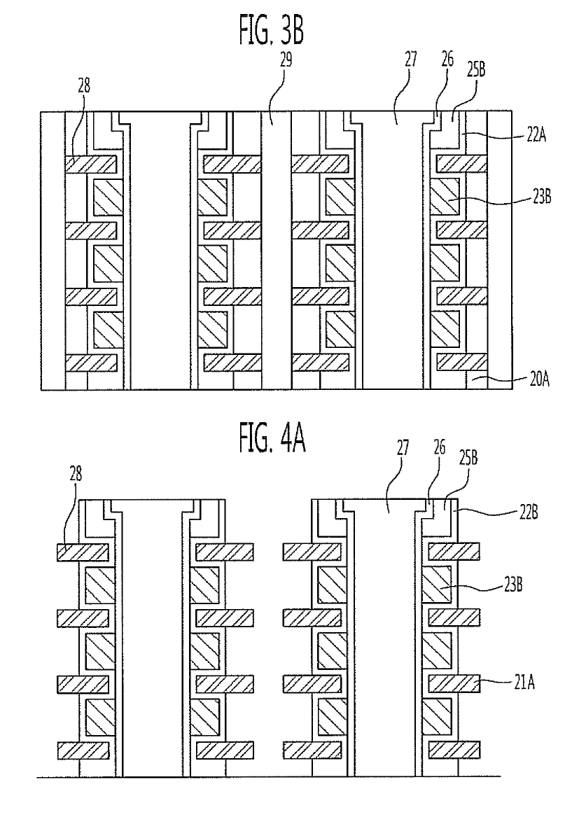

FIG. 5 is a sectional view showing a structure of a 3-D non-volatile memory device according to a fourth embodiment of the present invention.

The 3-D non-volatile memory device according to the fourth embodiment of the present invention includes a lower select gate, a plurality of memory cells, and an upper select gate which are sequentially stacked over a substrate 50. Accordingly, strings are arranged to extent in a vertical direction to the substrate.

A process of fabricating the 3-D non-volatile memory device according to the fourth embodiment is described in short below.

First, an interlayer insulating layer 51 and a conductive layer 52 are formed over a substrate 50 including a source region S. Trenches are formed by etching the interlayer insulating layer 51 and the conductive layer 52. After forming a gate insulating layer 53 on the inner walls of each of the trenches, a channel layer 54 is formed on the gate insulating layer 53. An example that the channel layer 54 is formed to fully fill the central region of the trench is illustrated in FIG. 5, but the channel layer 54 may be formed so that the central region is not filled. In this case, an insulating layer is filled in the central region.

Next, a plurality of memory cells is formed. A process of forming the plurality of memory cells may be performed by using the process described in any one of the first to third embodiments.

A conductive layer 55 and an interlayer insulating layer 56 are formed over the plurality of memory cells. Trenches are formed by etching the conductive layer 55 and the interlayer insulating layer 56. A gate insulating layer 57 is formed on the inner walls of the trenches. A channel layer 58 is formed on the gate insulating layer 57.

An example that the channel layer 58 is formed to fully fill the central region of the trench is illustrated in FIG. 5, but the channel layer 58 may be formed so that the central region is not filled. In this case, an insulating layer is filled in the central region.

Bit lines BL coupled to the channel layer 58 are formed.

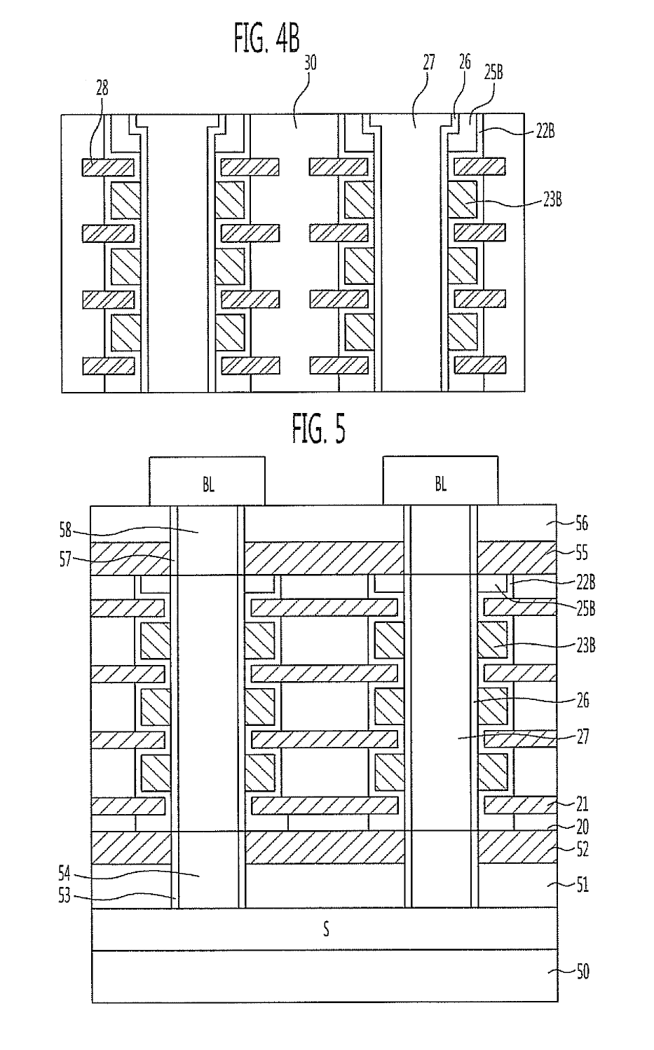

FIG. 6 is a sectional view showing a structure of a 3-D non-volatile memory device according to a fifth embodiment of the present invention.

The 3-D non-volatile memory device according to the fifth embodiment of the present invention includes a plurality of memory cells stacked over a substrate and a select gate formed over the memory cells. Accordingly, strings are arranged in a U form.

A process of manufacturing the 3-D non-volatile memory device according to the fifth embodiment is described in short below.

First, after forming a first trench by etching a pipe gate 60, a first sacrificial layer is formed within the first trench. The first sacrificial layer may be formed of a nitride layer.

A plurality of first material layers 21 and a plurality of second material layers 20 are alternately formed over the pipe gate 60 in which the first sacrificial layer is filled. A pair of second trenches coupled to the first trench is formed by etching the plurality of first material layers 21 and the plurality of second material layers 20.

Floating gate regions are formed by recessing the plurality of second material layers, exposed to the inner walls of the second trenches, by a specific depth. A first charge blocking layer 22B is formed on the inner surfaces of the second trenches in each of which the floating gate regions are formed. Next, floating gates 23B are formed by processes of forming a first conductive layer, a second sacrificial layer, and a second charge blocking layer 25B. Here, a process of forming the floating gates 23B may be performed by using the process described in any one of the first to third embodiments.

Next, the first sacrificial layer exposed to the bottoms of the pair of second trenches is removed. A tunnel insulating layer 26 is formed on the inner surfaces of the first trench and the pair of second trenches. A first channel layer 27 is formed on the tunnel insulating layer 26. An example that the first channel layer 27 is formed to fully fill the central region of the first trench and the second trenches is illustrated in FIG. 6, but the first channel layer 27 may be formed so that the central region is not filled. In this case, an insulating layer is filled in the central region.

A conductive layer 61 and an interlayer insulating layer 62 are formed over the result in which the first channel layer 27 is formed. Trenches are formed by etching the conductive layer 61 and the interlayer insulating layer 62. A gate insulating layer 63 is formed on the inner walls of the trenches. A second channel layer 64 is formed on the gate insulating layer 63. An example that the second channel layer 64 is formed to fully fill the central region of the trenches is illustrated in FIG. 6, but the second channel layer 64 may be formed so that the central region is not filled. In this case, an insulating layer is filled in the central region. Accordingly, first and second select gates are formed.

A slit is formed between the pair of first/second channels by etching the interlayer insulating layer 62, the conductive layer 61, the plurality of first material layers 21, and the plurality of second material layers 20. An insulating layer 65 is filled in the slit. Accordingly, the source-side word lines and the drain-side word lines of one string are separated from each other.

Here, a slit may be formed between f adjacent strings at the same time. In this case, the source-side word lines or the drain-side word lines of the adjacent strings may be separated from each other.

Next, a source line SL coupled to the channel 64 of the first select gate and a bit line BL coupled to the channel 64 of the second select gate are formed,

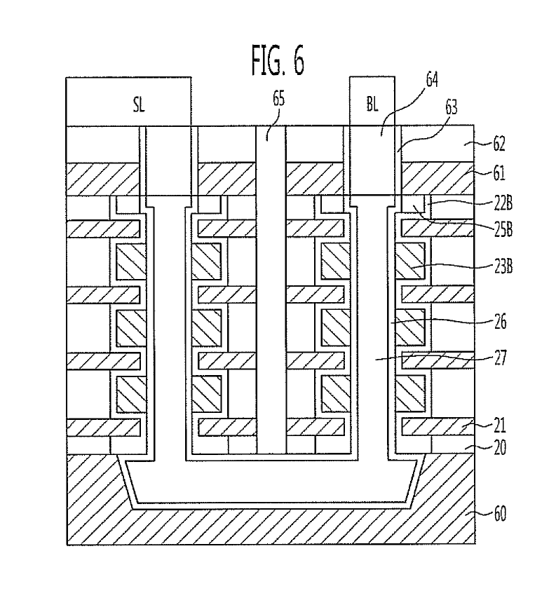

FIG. 7 shows a construction of a memory system according to an exemplary embodiment of the present invention.

As shown in FIG. 7, the memory system 100 according to the embodiment of the present invention includes a non-volatile memory device 120 and a memory controller 110.

The non-volatile memory device 120 is formed to have a cell structure, such as that described in any one of the first to fifth embodiments. Furthermore, the non-volatile memory device 120 may be a multi-chip package including a plurality of flash memory chips.

The memory controller 110 controls the non-volatile memory device 120 and may include SRAM 111, a Central Processing Unit (CPU) 112, a host interface (I/F) 113, an ECC circuit 114, and a memory I/F 115. The SRAM 111 is used as the operating memory of the CPU 112. The CPU 112 performs an overall control operation for the data exchange of the memory controller 110. The host I/F 113 is equipped with the data exchange protocol of a host coupled to the memory system 100. Furthermore, the ECC 114 circuit detects and corrects errors included in data read out from the non-volatile memory device 120. The memory I/F 115 performs an interfacing operation with the non-volatile memory device 120. The memory controller 110 may further include RCM for storing code data for an interfacing operation with the host.

The memory system 100 constructed as described above may be a memory card or a Solid State Disk (SSD) in which the non-volatile memory device 120 and the controller 110 are combined. For example, if the memory system 100 is an SSD, the memory controller 110 may communicate with the outside (e.g., a host) through one of various interface protocols, such as USB, MMC, PCI-E, SATA, PATA, SCSI, ESDI, and IDE.

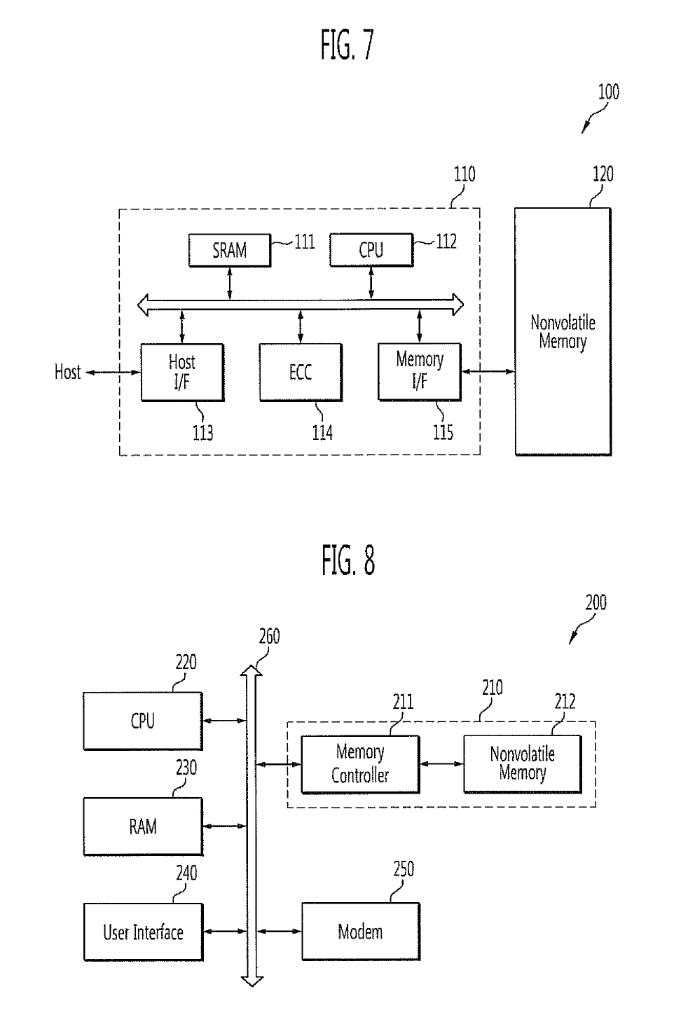

FIG. 8 shows a construction of a computing system according to an exemplary embodiment of the present invention.

As shown in FIG. 8, the computing system 200 according to the embodiment of the present invention may include a CPU 220, RAM 230, a user interface 240, a modem 250, and a memory system 210 electrically coupled a system bus 260. If the computing system 200 is a mobile device, the computing system 200 may further include a battery for supplying operating voltages to the computing system 200. The computing system 200 may further include application chipsets, a Camera Image Processor (CIS), mobile DRAM, and so on.

The memory system 210 may include a non-volatile memory device 212 and a memory controller 211, such as those described above with reference to FIG. 7.

The 3-D floating gates type non-volatile memory device according to the present invention may have more improved performance and reliability than a known 3-D charge trap type non-volatile memory device. In particular, since one memory cell includes one floating gate and two control gate electrodes as described above, memory cells may be driven more easily using a low program voltage and a low erase voltage. Furthermore, an interference effect may be reduced as compared with a known art because the charge blocking layer is formed to surround the entire surface of the floating gates.

Furthermore, in accordance with the present invention, a process of etching the conductive layer for forming the floating gates is performed though two split processes, and the second charge blocking layer is further formed on the upper side of the trench. Accordingly, a word line formed at the top and the charge blocking layer may be prevented from being damaged in a process of etching the conductive layer.

What is claimed is:

1. A method of manufacturing a 3-Dimensional (3-D) non-volatile memory device, the method comprising:
forming first material layers and second material layers alternately;
forming at least one first trench by etching the first material layers and the second material layers;
forming floating gate regions by recessing the second material layers, exposed to the first trench;
forming a first charge blocking layer on surfaces of the first trench and the floating gate regions;
forming a first conductive layer on the first charge blocking layer;
etching the first conductive layer formed on an upper side of the first trench;
forming a second charge blocking layer on the first charge blocking layer exposed by etching the first conductive layer; and
forming floating gates in the respective floating gate regions by etching the first conductive layer.

2. The method of claim 1, further comprising:
forming a first sacrificial layer within the first trench after the forming of the first conductive layer; and
removing the first sacrificial layer after the forming of the second charge blocking layer.

3. The method of claim 2, wherein a top surface of the first sacrificial layer is higher than a top surface of the first material layer formed at a top, among the plurality of first material layers.

4. The method of claim 2, wherein the first sacrificial layer is formed of a flowable oxide layer.

5. The method of claim 1, wherein the first material layers and the second material layers are formed of material having a high etch selectivity ratio to each other.

6. The method of claim 1, wherein the first conductive layer fills the first trench except a central region thereof in the forming of the first conductive layer.

7. The method of claim 1, wherein the etching of the first conductive layer formed on the upper side of the first trench is performed by an etch-back process or a wet etch process.

8. The method of claim 1, further comprising:
forming a tunnel insulating layer on an inner wall of the first trench in which the floating gates are formed; and
forming a channel layer on the tunnel insulating layer.

9. The method of claim 8, further comprising:
forming a slit between the first trenches by etching the first material layers and the second material layers after forming the channel layer;
recessing the first material layers exposed to the slit; and
filling second conductive layers in regions from which the first material layers are recessed.

10. The method of claim 8, further comprising:
forming a slit between the first trenches by etching the first material layers and the second material layers after forming the channel layer;
recessing the second material layers exposed to the slit; and
filling interlayer insulating layers in regions from which the second material layers are recessed.

11. The method of claim 1, further comprising:
forming a second trench by etching a pipe gate before forming the first material layers and the second material layers; and
forming a second sacrificial layer within the second trench,
wherein a pair of the first trenches is coupled to the second trench in the forming of the at least one first trench.

12. The method of claim 11, further comprising:
removing the second sacrificial layer after forming the floating gates;
forming a tunnel insulating layer on inner surfaces of the pair of first trenches in which the floating gates are formed and an inner surface of the second trench; and
forming a channel layer on the tunnel insulating layer.

13. A 3-Dimensional (3-D) non-volatile memory device, comprising:
word lines and interlayer insulating layers alternately stacked over a substrate;
at least one first channel protruding from the substrate and penetrating the word lines and the interlayer insulating layers;
floating gates interposed between the first channel and the interlayer insulating layers and surrounding the first channel;
a first charge blocking layer interposed between the word lines and the floating gates; and
a second charge blocking layer formed on the first charge blocking layer surrounding a top word line of the word lines.

14. The 3-D non-volatile memory device of claim 13, further comprising:
a lower select gate formed under the word lines; and
an upper select gate formed over the word lines.

15. The 3-D non-volatile memory device of claim 13, further comprising:
a pipe gate formed under the word lines;
a second channel formed within the pipe gate and coupled to a pair of the first channels; and
a first select gate and a second select gate formed over the word lines.

16. A method of manufacturing a 3-Dimensional (3-D) non-volatile memory device, the method comprising:
forming first material layers and second material layers alternately;
forming at least one trench by etching the first material layers and the second material layers;
recessing the second material layers exposed to the first trench;
forming a first charge blocking layer on surfaces of the first material layers and the recessed second material layers;
forming a first conductive layer on the first charge blocking layer;
performing a first etching process to remove the first conductive layer formed on an upper region of the trench;
forming a second charge blocking layer on the first charge blocking layer exposed by the first etching process; and
performing a second etching process to form floating gates by removing the first conductive layer formed on a center region of the trench.

17. The method of claim 16, the forming of the first conductive layer comprising:
forming the first conductive layer to fill the trench except the center region thereof; and
forming a sacrificial layer to fill the center region of the trench.
